(19) United States
(12) Patent Application Publication
(10) Pub. No.: US 2026/0075762 A1
(43) Pub. Date: Mar. 12, 2026

(54) COOLING SYSTEM HAVING PHASE-CHANGE COOLANT MODULE

(71) Applicant: Quanta Computer Inc., Taoyuan City (TW)

(72) Inventors: Jen-Mao CHEN, Taoyuan City (TW); Wei-Te WANG, Taoyuan City (TW); Min Han LIU, Taoyan City (TW)

(21) Appl. No.: 18/882,594

(22) Filed: Sep. 11, 2024

(51) Int. Cl. H05K 7/20

(52) U.S. Cl. CPC H05K 7/2029

(57) ABSTRACT

A cooling system for a computing device includes a cold plate configured for conducting heat away from a heat source. The cooling system further includes a phase-change coolant module disposed between and in thermal contact with the heat source and the cold plate. The phase-change coolant module contains a phase-change coolant.

### FIELD OF THE INVENTION

The present invention relates generally to a cooling system, and more specifically, to a cooling system that includes a phase-change coolant module.

### BACKGROUND OF THE INVENTION

Traditional cold plate cooling systems utilize a chilled coolant, often water, to cool a heat source such as a computer device or chip. It has been observed that when heat from the heat source dissipates into a traditional cold plate, the heat will be concentrated in certain areas. This concentration of heat limits the overall heat dissipation. A need exists for a cold plate cooling system that has a high thermal conductivity in a direction orthogonal to the direction of heat flow, to reduce heat concentration and improve overall heat dissipation.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a cooling system for a computing device includes a cold plate configured for conducting heat away from a heat source. The cooling system further includes a phase-change coolant module disposed between and in thermal contact with the heat source and the cold plate. The phase-change coolant module contains a phase-change coolant.

According to certain aspects of the present disclosure, the phase-change coolant module is in thermal contact with the cold plate through at least a base of the cold plate. The phase-change coolant module is configured to be above and in thermal contact with the heat source.

According to certain aspects of the present disclosure, the phase-change coolant is configured to: at least partially vaporize from a liquid state to a vapor state in response to heat flow from the heat source; rise inside the phase-change coolant module in the vapor state; at least partially condense from the vapor state to the liquid state in response to heat flow to the cold plate; and fall inside the phase-change coolant module in the liquid state.

According to certain aspects of the present disclosure, the phase change coolant is water.

According to certain aspects of the present disclosure, the cold plate further has an internal flow channel including at least one fin that is in thermal contact with the base of the cold plate. The internal flow channel is configured to receive a liquid coolant.

According to certain aspects of the present disclosure, the liquid coolant is water.

According to certain aspects of the present disclosure, the cold plate further has a liquid coolant inlet in fluid communication with the internal flow channel and a liquid coolant outlet in fluid communication with the internal flow channel.

According to certain aspects of the present disclosure, the phase-change coolant module has a bottom surface configured to have an area larger than the heat source.

According to certain aspects of the present disclosure, a cooling system for a computing device includes a cold plate for conducting heat from a heat source. The cooling system further includes a phase-change coolant module disposed below and in thermal contact with a base of the cold plate. At least a portion of the phase-change coolant module extends above the base of the cold plate. The phase-change coolant module is configured to be disposed above and in thermal contact with the heat source. The phase-change coolant module contains a phase-change coolant.

According to certain aspects of the present disclosure, the phase-change coolant module is in thermal contact with the cold plate through the base and through the at least a portion of the phase-change coolant module that extends above the base.

According to certain aspects of the present disclosure, the phase-change coolant is configured to: at least partially vaporize from a liquid state to a vapor state in response to heat flow from the heat source; rise inside the phase-change coolant module in the vapor state; at least partially condense from the vapor state to the liquid state in response to heat flow to the cold plate; and fall inside the phase-change coolant module in the liquid state.

According to certain aspects of the present disclosure, the phase-change coolant is water.

According to certain aspects of the present disclosure, the cold plate further has an internal flow channel including at least one fin that is in thermal contact with the base of the cold plate. The internal flow channel is configured to receive a liquid coolant.

According to certain aspects of the present disclosure, the at least a portion of the phase-change coolant module that extends above the base is disposed in thermal contact with the at least one fin and at least in part in the internal flow channel.

According to certain aspects of the present disclosure, the at least a portion of the phase-change coolant module that extends above the base comprises a tube in fluid communication with an interior of the phase-change coolant module. The tube is disposed to extend transversely across the at least one fin and at least in part in the internal flow channel.

According to certain aspects of the present disclosure, the liquid coolant is water.

According to certain aspects of the present disclosure, the cold plate further has a liquid coolant inlet in fluid communication with the internal flow channel and a liquid coolant outlet in fluid communication with the internal flow channel.

According to certain aspects of the present disclosure, the phase-change coolant module further has a bottom surface configured to have an area larger than the heat source.

According to certain aspects of the present disclosure, facing sides of the phase-change coolant module and the cold plate have approximately equal areas.

According to certain aspects of the present disclosure, the at least a portion of the phase-change coolant module that extends above the base of the cold plate has a first height that is greater than a second height of a second portion of the phase-change coolant module that is disposed below the base of the cold plate.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is an exploded perspective schematic view showing a known cooling system.

FIG. 2 is an exemplary temperature map of a base of the known cooling system of FIG. 1.

FIG. 3 is an exploded perspective schematic view showing an embodiment of a cooling system, according to certain aspects of the present disclosure.

FIG. 4 is a schematic side view showing the cooling system of FIG. 3, according to certain aspects of the present disclosure.

FIG. 5 is a schematic diagram of a vaporization-condensation cycle for phase-change coolant inside a phase-change coolant module, according to certain aspects of the present disclosure.

FIG. 6 is an exemplary temperature map of a base of the cooling system of FIGS. 3 and 4, according to certain aspects of the present disclosure.

FIG. 7 is an exploded perspective schematic view showing another embodiment of a cooling system, according to certain aspects of the present disclosure.

FIG. 8 is a schematic side view showing the cooling system of FIG. 7, according to certain aspects of the present disclosure.

FIG. 9 is an exemplary temperature map of a base of the cooling system of FIGS. 7 and 8, according to certain aspects of the present disclosure.

### DETAILED DESCRIPTION

The current invention is a cooling system that includes a cold plate disposed above a phase-change coolant module. The phase-change coolant module is configured to be disposed above and in thermal contact with a heat source. The phase-change coolant module contains a phase-change coolant configured to undergo a vaporization-condensation cycle inside the phase-change coolant module. The vaporization-condensation cycle not only functions to dissipate heat, but also increases thermal conduction of heat in a horizontal direction, which reduces heat concentration and improves overall heat dissipation.

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation. ” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

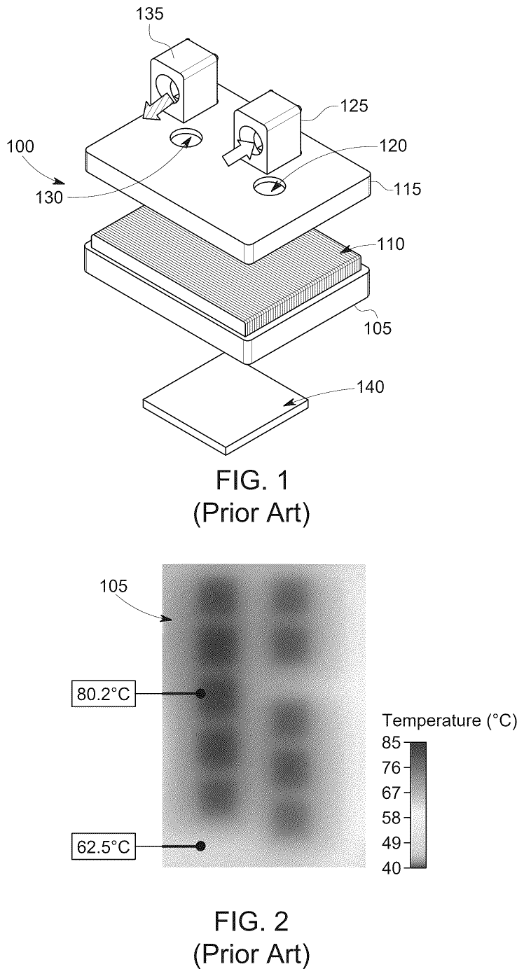

Referring to FIG. 1, known liquid cooling systems for computer chips include a traditional cold plate 100. For example, the traditional cold plate 100 includes a base 105, an arrangement of fins 110 attached to and extending from the base 105, and a cover 115. The cover seals to the base 105 over the fins 110. Liquid coolant, for example, water, flows through an inside of the cold plate 100 over the fins 110 to carry away heat conducted into the cold plate 100 through the base 105. A liquid coolant inlet 120 provides a passage for liquid coolant to enter the cold plate, for example, through an inlet fitting 125. A liquid coolant outlet 130 provides a passage for liquid coolant to exit the cold plate 100, for example, through an outlet fitting 135. In use, the cold plate 100 is positioned so that the base 105 is in thermal contact with a heat source 140, for example, a computer chip or a plurality of computer chips.

Referring to FIG. 2, a temperature map of the base 105 of a traditional cold plate 100 (FIG. 1) shows that the heat density on the traditional cold plate 100 is relatively high. The temperature map of the base 105 shows that when heat passes through the base 105 of the cold plate 100, the heat will be concentrated in certain areas, as evidenced by the ten distinct squares of higher temperature in FIG. 2. This concentration of the heat limits the heat dissipation performance of the traditional cold plate 100.

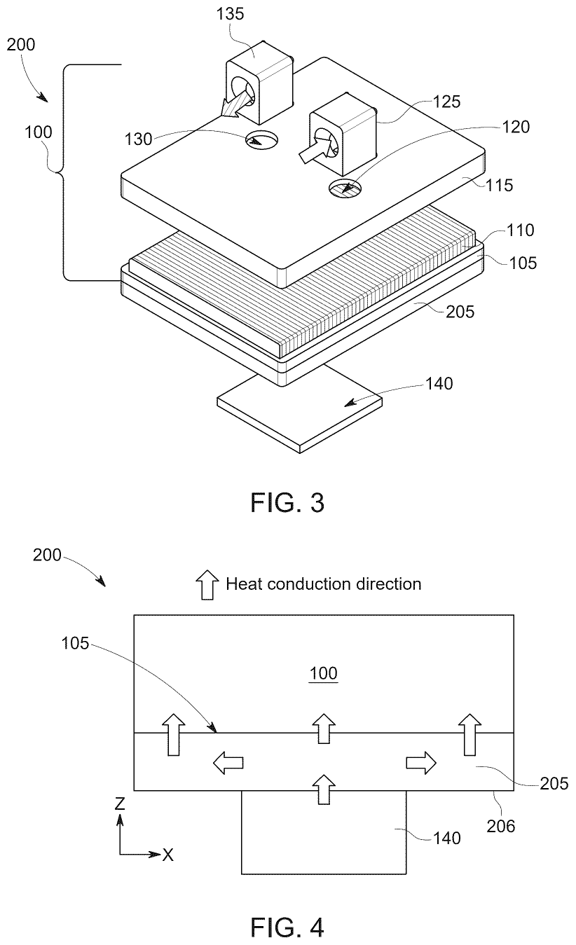

Referring to FIGS. 3 and 4, an embodiment of a cooling system 200 for a computing device includes a cold plate 100 and a phase-change coolant module 205. The cold plate 100 is configured to conduct heat away from a heat source 140. The phase-change coolant module 205 is disposed between and in thermal contact with the heat source 140 and the cold plate 100. In an embodiment, the phase-change coolant module 205 is in thermal contact with the cold plate 100 through at least a base 105 of the cold plate 100. The phase-change coolant module 205 is configured to be disposed above and in thermal contact with the heat source 140.

Referring to FIG. 3, in an embodiment, the cold plate 100 further has one or more fins 110 arranged on and extending from the base 105. The one or more fins 110 define an internal flow channel that is in thermal contact with the base 105 of the cold plate 100. The internal flow channel is configured to receive a liquid coolant, for example, water. The cold plate 100 has a liquid coolant inlet 120 in fluid communication with the internal flow channel, for example, through an inlet fitting 125. The cold plate 100 further has a liquid coolant outlet 130 in fluid communication with the internal flow channel, for example, through an inlet fitting 135. Referring to FIG. 4, in an embodiment, the phase-change coolant module 205 has a bottom surface 206 configured to have an area larger than the heat source 140.

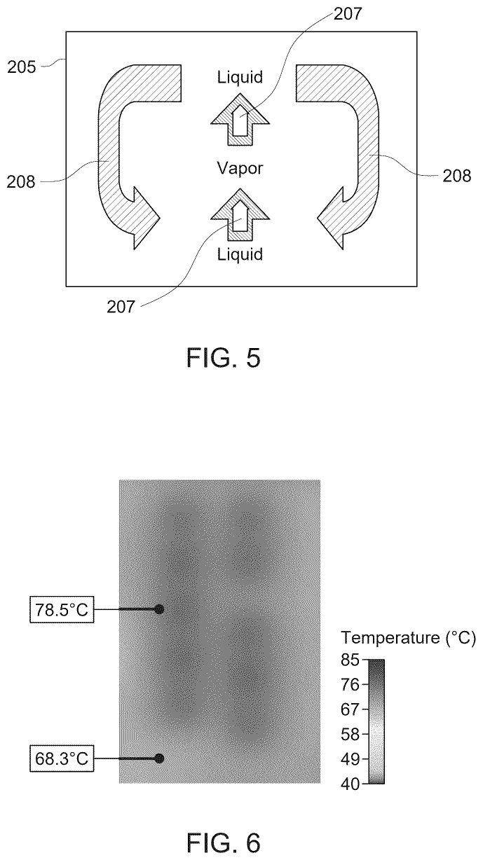

Referring to FIG. 5, in an embodiment, the phase-change coolant module 205 contains the phase-change coolant, which is configured to undergo a vaporization-condensation cycle inside the phase-change coolant module 205. As part of the vaporization-condensation cycle, the phase-change coolant is configured to at least partially vaporize from a liquid state to a vapor state in response to receiving heat flow from the heat source 140. The phase-change coolant in the vapor state rises inside the phase-change coolant module 205 as schematically indicated by the arrows 207 in FIG. 5. The phase-change coolant at least partially condenses from the vapor state to the liquid state in response to heat flow to the cold plate 100. The phase-change coolant subsequently falls inside the phase-change coolant module 205 in the liquid state as schematically indicated by the arrows 208 in FIG. 5, and again is at least partially vaporized to repeat the cycle.

An exemplary phase-change coolant includes, for example without limitation, water. The vaporization temperature (boiling temperature) of a liquid is dependent on the pressure of the liquid. Changing the pressure inside the phase-change coolant module 205 changes the temperature of vaporization of the phase-change coolant therein. Therefore, a pressure inside the phase-change coolant module 205 that is less than 1 atmosphere results in the vaporization temperature of water inside the phase-change coolant module 205 to be less than 100 degrees Celsius (° C.). A vaporization temperature for water in a range from about 60 to 80° C. suitable for use herein is achieved by lowering the pressure inside the phase-change coolant module 205 to a range from about 0.2 to about 0.47 atmospheres. In other embodiments, the phase-change coolant used inside the phase-change coolant module 205 can be a liquid other than water held inside the phase-change coolant module 205 at a pressure that achieves the desired vaporization temperature range.

The vaporization-condensation cycle of the phase-change coolant is advantageous to the cooling system 200 in at least two ways. First, the latent heat of vaporization of a liquid is often two to three orders of magnitude higher than the specific heat for the liquid at a comparable temperature. For example, the latent heat of vaporization of water at 1 atmosphere pressure is about 2260 Joules/gram (J/g), whereas the specific heat of water at 1 atmosphere pressure is about 4.2 J/g/degree Kelvin (K). This means that the vaporization of water can absorb over 500 times as much heat as does raising the temperature of the water by 1 K. This represents a very large increase in the transferrable heat out from the heat source 140.

Referring to FIGS. 4 and 5, a second way in which the vaporization-condensation cycle of the phase-change coolant is beneficial is the natural convection style looping motion of the phase-change coolant. In addition to rising, the phase-change coolant also spreads out horizontally (see FIG. 5), thus improving the thermal conduction across the phase-change coolant module 205 in the horizontal direction (see FIG. 4). This increased thermal conduction helps spread out hot spots and results in better overall cooling.

FIG. 6 shows a temperature map of the bottom of an exemplary phase-change coolant module 205 (FIGS. 3-5). A comparison of the temperature map in FIG. 6 with the temperature map in FIG. 2 shows that the heat density is reduced. The observed reduction in heat density is at least in part a result of the enhanced thermal conductivity of the phase-change coolant module 205. The reduced heat density of the bottom of the phase-change coolant module 205 makes it easier for the cooling system 200 (FIG. 3) to take away the heat from the heat source 140 (FIGS. 3 and 4). Further comparing the temperature map in FIG. 6 with the temperature map in FIG. 2 shows that peak temperature of the heat source 140 is reduced from about 80.2° C. to about 78.5° C.

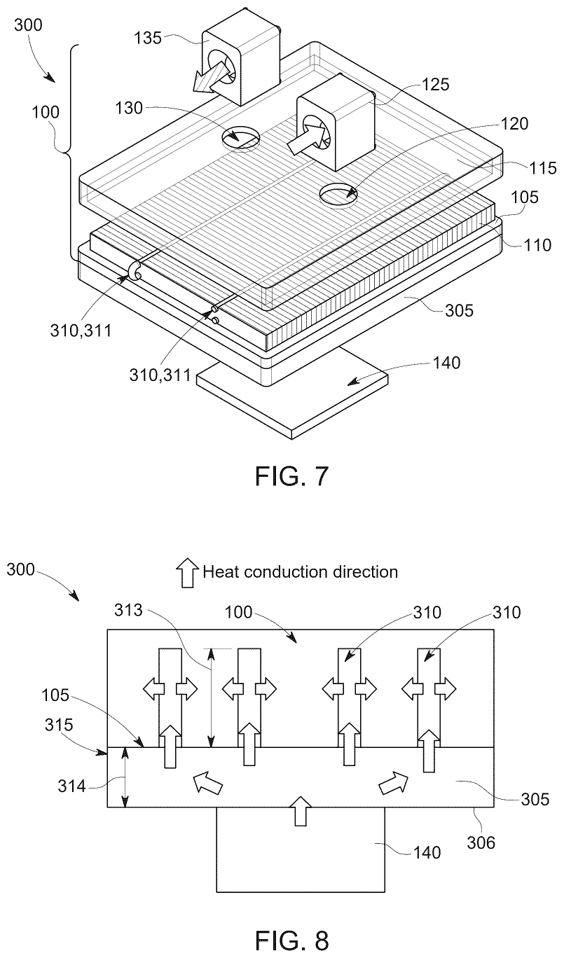

Referring to FIGS. 7 and 8, in an embodiment, a cooling system 300 for a computing device includes a cold plate 100 for conducting heat from the heat source 140, and a phase-change coolant module 305 disposed below and in thermal contact with a base 105 of the cold plate 100. In this embodiment, at least a portion 310 of the phase-change coolant module 305 extends above the base 105 of the cold plate 100. The phase-change coolant module 305 is configured to be disposed above and in thermal contact with the heat source 140. The phase-change coolant module 305 is in thermal contact with the cold plate 100 through the base 105 and through the portion 310 of the phase-change coolant module 305 that extends above the base 105.

In an embodiment, the phase-change coolant module 305 contains a phase-change coolant, which is configured to undergo a vaporization-condensation cycle inside the phase-change coolant module 305. As part of the vaporization-condensation cycle, the phase-change coolant is configured to at least partially vaporize from a liquid state to a vapor state in response to receiving heat flow from the heat source 140. The phase-change coolant in the vapor state rises inside the phase-change coolant module 305. The phase-change coolant at least partially condenses from the vapor state to the liquid state in response to heat flow to the cold plate 100. The phase-change coolant subsequently falls inside the phase-change coolant module 305 in the liquid state, and again is at least partially vaporized to repeat the cycle. As noted above, exemplary phase change coolants include, for example without limitation, water.

In an embodiment, the cold plate 100 has one or more fins 110 arranged on and extending from the base 105. The one or more fins 110 define an internal flow channel that is in thermal contact with the base 105 of the cold plate 100. The internal flow channel is configured to receive a liquid coolant, for example, water. The cold plate 100 has a liquid coolant inlet 120 in fluid communication with the internal flow channel, for example, through an inlet fitting 125. The cold plate 100 further has a liquid coolant outlet 130 in fluid communication with the internal flow channel, for example, through an outlet fitting 135.

In an embodiment, the at least a portion 310 of the phase-change coolant module 305 that extends above the base 105 is disposed in thermal contact with at least one fin 110 and is disposed at least in part in the internal flow channel. In an embodiment, the at least a portion 310 of the phase-change coolant module 305 that extends above the base 105 includes a tube 311 in fluid communication with an interior of the phase-change coolant module 305. The tube 311 is disposed to extend transversely across the at least one fin 110 and at least in part in the internal flow channel. The phase change coolant, when in the vapor state, rises into the tube 311. The phase change coolant in the vapor state condenses inside the tube 311 to a liquid state, thereby transferring heat to the at least one fin 110 and the liquid coolant flowing through the internal flow channel.

As noted above for the cooling system 200 (FIG. 3), using the latent heat of vaporization of a liquid to absorb waste heat and the looping pattern of the vaporization-condensation cycle are advantageous to overall cooling of a heat source 140. Referring to FIG. 8, the internal geometry of the phase-change coolant module 305 relative to the cold plate 100 provides another advantageous aspect for cooling. By extending the portions 310 of the phase-change coolant module 305 into thermal contact with the at least one fin 110 and the liquid coolant in the internal flow channel, the thermal contact area for heat transfer is increased. The increase in heat transfer area is advantageous for a greater transfer of heat from the phase-change coolant module 305 to the cold plate 100.

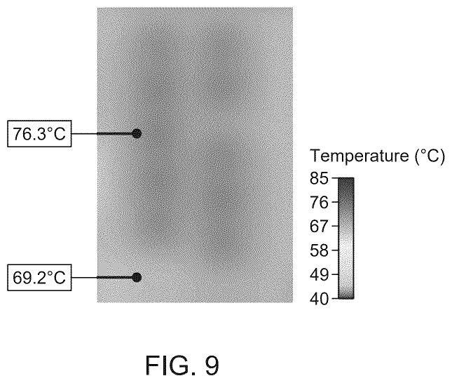

FIG. 9 shows a temperature map of the bottom of an exemplary phase-change coolant module 305 (FIGS. 7 and 8). A comparison of the temperature map in FIG. 9 with the temperature map in FIG. 2 shows that the heat density is reduced. The observed reduction in heat density is at least in part a result of the enhanced thermal conductivity of the phase-change coolant module 305 and the increased surface area for heat transfer between the phase-change coolant module 305 and the cold plate 100 (FIGS. 7 and 8). The reduced heat density of the bottom of the phase-change coolant module 305 makes it easier for the cooling system 300 (FIGS. 7 and 8) to take away the heat from the heat source 140 (FIGS. 7 and 8). Further comparing the temperature map in FIG. 9 with the temperature map in FIG. 2 shows that peak temperature of the heat source 140 is reduced from about 80.2° C. to about 76.3° C.

Referring back to FIGS. 7 and 8, in an embodiment, the phase-change coolant module 305 further has a bottom surface 306 configured to have an area larger than the heat source 140. In an embodiment, facing sides of the phase-change coolant module 305 and the cold plate 100 have approximately equal areas. In an embodiment, the at least a portion 310 of the phase-change coolant module 305 that extends above the base 105 of the cold plate 100 has a first height 313 that is greater than a second height 314 of a second portion 315 of the phase-change coolant module 305.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A cooling system for a computing device, the cooling system comprising:
a cold plate configured for conducting heat away from a heat source; and
a phase-change coolant module disposed between and in thermal contact with the heat source and the cold plate, the phase-change coolant module containing a phase-change coolant.

2. The cooling system of claim 1, wherein the phase-change coolant module is in thermal contact with the cold plate through at least a base of the cold plate, the phase-change coolant module being configured to be above and in thermal contact with the heat source.

3. The cooling system of claim 2, wherein the phase-change coolant is configured to:
at least partially vaporize from a liquid state to a vapor state in response to heat flow from the heat source;
rise inside the phase-change coolant module in the vapor state;
at least partially condense from the vapor state to the liquid state in response to heat flow to the cold plate; and
fall inside the phase-change coolant module in the liquid state.

4. The cooling system of claim 3, wherein the phase-change coolant is water.

5. The cooling system of claim 3, wherein the cold plate further has an internal flow channel including at least one fin that is in thermal contact with the base of the cold plate, the internal flow channel being configured to receive a liquid coolant.

6. The cooling system of claim 5, wherein the liquid coolant is water.

7. The cooling system of claim 5, wherein the cold plate further has a liquid coolant inlet in fluid communication with the internal flow channel and a liquid coolant outlet in fluid communication with the internal flow channel.

8. The cooling system of claim 1, wherein the phase-change coolant module has a bottom surface configured to have an area larger than the heat source.

9. A cooling system for a computing device, the cooling system comprising:
a cold plate for conducting heat from a heat source; and
a phase-change coolant module disposed below and in thermal contact with a base of the cold plate, at least a portion of the phase-change coolant module extending above the base of the cold plate, the phase-change coolant module being configured to be disposed above and in thermal contact with the heat source, the phase-change coolant module containing a phase-change coolant.

10. The cooling system of claim 9, wherein the phase-change coolant module is in thermal contact with the cold plate through the base and through the at least a portion of the phase-change coolant module that extends above the base.

11. The cooling system of claim 10, wherein the phase-change coolant is configured to:
at least partially vaporize from a liquid state to a vapor state in response to heat flow from the heat source;
rise inside the phase-change coolant module in the vapor state;
at least partially condense from the vapor state to the liquid state in response to heat flow to the cold plate; and
fall inside the phase-change coolant module in the liquid state.

12. The cooling system of claim 11, wherein the phase-change coolant is water.

13. The cooling system of claim 11, wherein the cold plate further has an internal flow channel including at least one fin in thermal contact with the base of the cold plate, the internal flow channel being configured to receive a liquid coolant.

14. The cooling system of claim 13, wherein the at least a portion of the phase-change coolant module that extends above the base is disposed in thermal contact with the at least one fin and at least in part in the internal flow channel.

15. The cooling system of clam 14, wherein the at least a portion of the phase-change coolant module that extends above the base comprises a tube in fluid communication with an interior of the phase-change coolant module, wherein the tube is disposed to extend transversely across the at least one fin and at least in part in the internal flow channel.

16. The cooling system of claim 13, wherein the liquid coolant is water.

17. The cooling system of claim 13, wherein the cold plate further has a liquid coolant inlet in fluid communication with the internal flow channel and a liquid coolant outlet in fluid communication with the internal flow channel.

18. The cooling system of claim 9, wherein the phase-change coolant module further has a bottom surface configured to have an area larger than the heat source.

19. The cooling system of claim 9, wherein facing sides of the phase-change coolant module and the cold plate have approximately equal areas.

20. The cooling system of claim 9, wherein the at least a portion of the phase-change coolant module that extends above the base of the cold plate has a first height that is greater than a second height of a second portion of the phase-change coolant module that is disposed below the base of the cold plate.
